(19) United States
(12) Patent Application Publication
(10) Pub. No.: US 2016/0268713 A1
(43) Pub. Date: Sep. 15, 2016

(54) CONNECTOR TO SECURE ASOLID STATE DEVICE IN AN OFF MOTHERBOARD LOCATION

(71) Applicant: HEWLETT PACKARD ENTERPRISE DEVELOPMENT LP, Houston, TX (US)

(72) Inventors: John Norton, Houston, TX (US); Scott W. BRIGGS, Cypress, TX (US); James Kenneth YATES, Houston, TX (US); Robert E. KRANCHER, Cypress, TX (US); Paul KALER, Houston, TX (US)

(21) Appl. No.: 15/033,221

(22) PCT Filed: Dec. 19, 2013
(86) PCT No.: PCT/US2013/076493

§ 371 Date: Apr. 29, 2016

(51) Int. Cl. H01R 12/70; H01R 12/72; G06F 13/40; H05K 7/10

(52) U.S. Cl. CPC H01R 12/7076; H05K 7/10; H01R 12/721; G06F 13/4068

(57) ABSTRACT

Examples herein disclose a connector integrated with a power cable and a signal cable. The connector secures a solid state device in an off motherboard location.

### BACKGROUND

A motherboard is a main printed circuit board (PCB) responsible for many of the operations and functions of a computing system. As such, the motherboard may include various electrical components within a computing system, such as the central processing unit, memory, and may provide connectors for other peripherals.

### BRIEF DESCRIPTION OF THE DRAWINGS

In the accompanying drawings, like numerals refer to like components or blocks. The following detailed description references the drawings, wherein:

FIG. 1 is a block diagram of an example connector including an electrical interface integrated with a power cable and a signal cable, the example connector is further including a mounting interface to secure a solid state device in an off motherboard location;

FIG. 2 is an example assembly including a connector integrated with a power cable to provide power from a power supply and a signal cable to provide signals between a solid state device and a motherboard, the assembly includes a mounting interface and mechanical fastener to secure and align the solid state device to a server chassis;

FIG. 3 is a side perspective view of an example assembly including a connector, cables, solid state device, and mechanical fastener;

FIG. 4 is a flowchart of an example method to secure a solid state device in an off motherboard location by integrating a power cable and a signal cable into a connector and mounting the solid state device with the connector in the off motherboard location; and

FIG. 5 is a flowchart of an example method to secure a solid state device in an off motherboard location by mounting the solid state device with a connector in the off motherboard location, aligning the solid state device with a server chassis, and securing the solid state device with a mechanical fastener to the server chassis.

### DETAILED DESCRIPTION

Including various electrical components on a motherboard takes up much space and volume which may limit space on the printed circuit board. Additionally, this may inhibit design flexibility of placement of the motherboard within a computing system. For example, the placement of the motherboard may be limited to areas within a computing system due to the space and volume constraints on the motherboard. Further, integrating a storage device onto the motherboard may include a separate connection to the motherboard which further impacts the space on the printed circuit board.

To address these issues, examples disclosed herein provide an assembly including a connector for securing a solid state device in an off motherboard location. The solid state device includes an electronic circuit which may provide storage and other functionality within a computing system. The off motherboard location is considered a physical location within the computing system different from a location of the motherboard. Securing the solid state device in the off motherboard location, provides flexibility to design and placement of the solid state device. This flexibility may also provide better space utilization further enabling an overall real estate reduction in a computing system. Further, securing the solid state device in the off motherboard location saves space and volume on the motherboard.

Additionally, the connector includes an electrical interface integrated with a power cable and a signal cable. The power cable provides power to the solid state device and the signal cable provides signals between the solid state device and the computing system. Providing signals and power between the solid state device and the computing system enables the connector to provide reliable electrical mating. Additionally, providing signals between the solid state device and the computing system enables the motherboard to communicate and/or access the so id state device even though the solid state device is located in a different area than the motherboard.

Further, the connector includes a mounting interface to secure the solid state device with the connector in the off motherboard location. The mounting interface brings together the connector and the solid state device providing electrical connections to the electrical interface integrated with the cables. Additionally, the mounting interface secures the solid state device to the connector in the off motherboard connection. This enables the connector with the mounting interface to be placed in several off motherboard locations within the computing system.

In another example discussed herein the solid state device provides storage within a server. In this example, a server chassis may receive the connector to align the solid state device in the off motherboard location. Providing storage within the server enables additional storage within the server when the motherboard may be limited in space. Additionally, the server chassis receiving the connector further provides flexibility to locate the connector and the solid state device where there may be available space.

In a further example discussed herein, the solid state device is located in the off motherboard location with a tolerance between the solid state device and the server chassis. The tolerance is a physical dimension of space between the solid state device and the server chassis. In this example, the server chassis may consist of an electrical conduction material, thus the tolerance may prevent the solid state device from grounding to the server chassis.

In summary, examples disclosed herein a flexible design through securing a solid state device in an off motherboard location. Securing the solid state device in the off motherboard location, saves space and volume on a motherboard which may provide overall better space utilization.

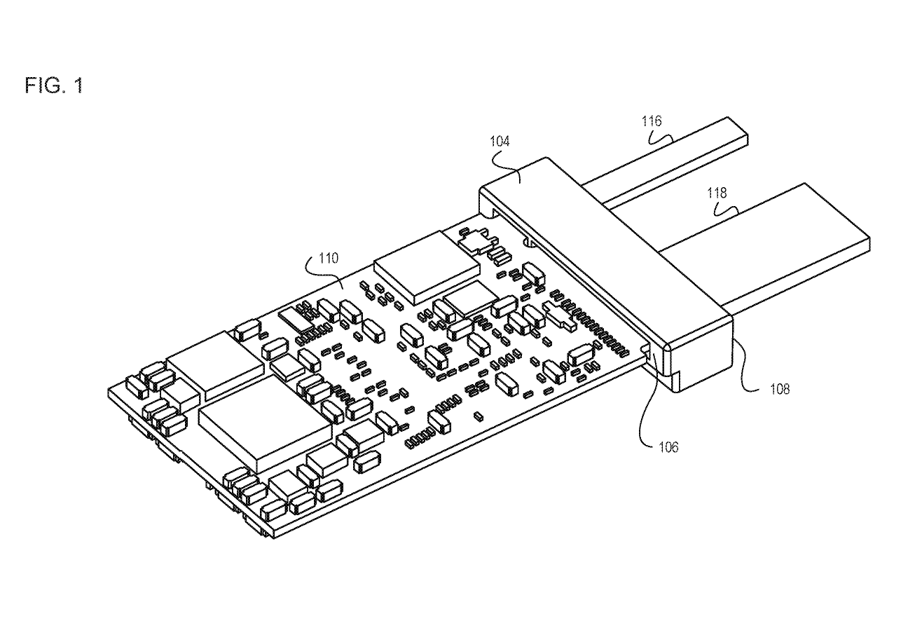

Referring now to the figures, FIG. 1 is a block diagram of an example connector 104 including an electrical interface 108 and a mounting interface 106 to secure a solid state device 110 in an off motherboard location. The off motherboard location is a physical location apart from a motherboard. In one implementation, the off motherboard location is a different physical location from the motherboard. For example, the off motherboard location may include the location within the computing device that is not above, below, and/or directly connected to the motherboard. The electrical interface 108 integrates a power cable 116 and a signal cable 118 to provide power and signals between the solid state device 110 and a computing system. The components of FIG. 1 including the solid state device 110, connector 104, mounting interface 106, electrical interface 108, and cables 116 and 118 are considered internal components within a computing device. In one implementation, the components are internal to a server. The solid state device 110 and the connector 104 including the electrical interface 108 and the mounting interface 106 are located in the off motherboard location. Locating the connector 104 and the solid state device 110 in the off motherboard location, provides a flexibility in a design of the computing device saving space and/or volume on a motherboard associated with the computing device. In another implementation, the power cable 116 is connected to a power supply (not illustrated) to provide power to the solid state device 110. Additionally in this implementation, the signal cable 118 is connected to a motherboard (not illustrated) to provide signals between the solid state device 110 and the motherboard. In a further implementation, the connector 114 may be included as part of an assembly to secure the solid state device 110 to a chassis. These implementations are described in detail in the next figure.

The connector 104 is an electrical device for bringing together electrical circuits as an interface using a mechanical assembly. The connector 104 includes the electrical interface 108 which integrates the power cable 116 and the signal cable 118. The connector 104 also includes the mounting interface 106 which connects the solid state device 110 to the connector 104. Including the electrical interface 108 and the mounting interface 106 as part of the connector 104, enables the connector 104 to form electrical connections between the solid state device 110 and the cables 116 and 118. In this implementation, the connector 104 provides reliable mating between electrical contacts on the solid state device 110 and the cables 116 and 118. In one implementation, the solid state device 110 may be directly connected into the connector 104. In this implementation, the solid state device 110 may be manually plugged into the mounting interface 106. Implementations of the connector 104 include an electrical connector, mechanical connector, power connector, or other type of assembly to provide reliable electrical contacts between the solid state device 110 and the cables 116 and 118.

The electrical interface 108 is a physical interface which joins the power cable 116 and the signal cable 118 to form part of the connector 104. The electrical interface 108 integrates the cables 116 and 118 to provide power and signals to the solid state device 110. Providing signals between the solid state device 110 and the computing system enables a motherboard to communicate and/or access the solid state device 110 even though the solid state device 110 is located in a different physical location from the motherboard.

The power cable 116 is an assembly which includes at least one electrical conductor used for a transmission of electrical power from a power supply (not illustrated) to the solid state device 110. In one implementation, the power cable 116 may be connected to the power supply in which to provide an electrical charge through the power cable 116 and to the solid state device 110. The solid state device 110 may serve as a storage device for the computing device, thus applying the electrical charge to the solid state device 110 enables operations, such as read and/or write data within the solid state device 110.

The signal cable 118 includes at least one transmission medium in which to transmit signals between the solid state device 110 and the computing system. In one implementation, the signal cable 118 is connected to the motherboard within the computing system to transmit signals between the motherboard and the solid state device 110.

The mounting interface 106 is a physical interface which brings together the solid state device 110 to the connector 104. The mounting interface 106 secures the solid state device 110 to the connector 104, thus enabling the off motherboard location of the solid state device 110. In one implementation, the mounting interface 106 includes a holding mechanism which securely holds the solid state device to the connector 104.

The solid state device 110 is a data storage device which may include integrated circuit assemblies as memory to store data persistently. As such, implementations of the solid state device 110 include flash-based memory, dynamic random access memory, solid state storage, hard drive, storage area, expansion card, or other type of memory capable of storing data persistently. In one implementation, the solid state device 110 may provide storage and other functionality within the computing device. In another implementation, the solid state device 110 includes an M.2 device which provides additional storage within the computing device. This implementation may provide a more flexible physical specification, thus reducing an overall real estate within a computing device. Although FIG. 1 describes the solid state device 110 as a storage-based device, this was done for clarification purposes. For example, the solid state device 110 may include an auxiliary processing unit, network interface, etc.

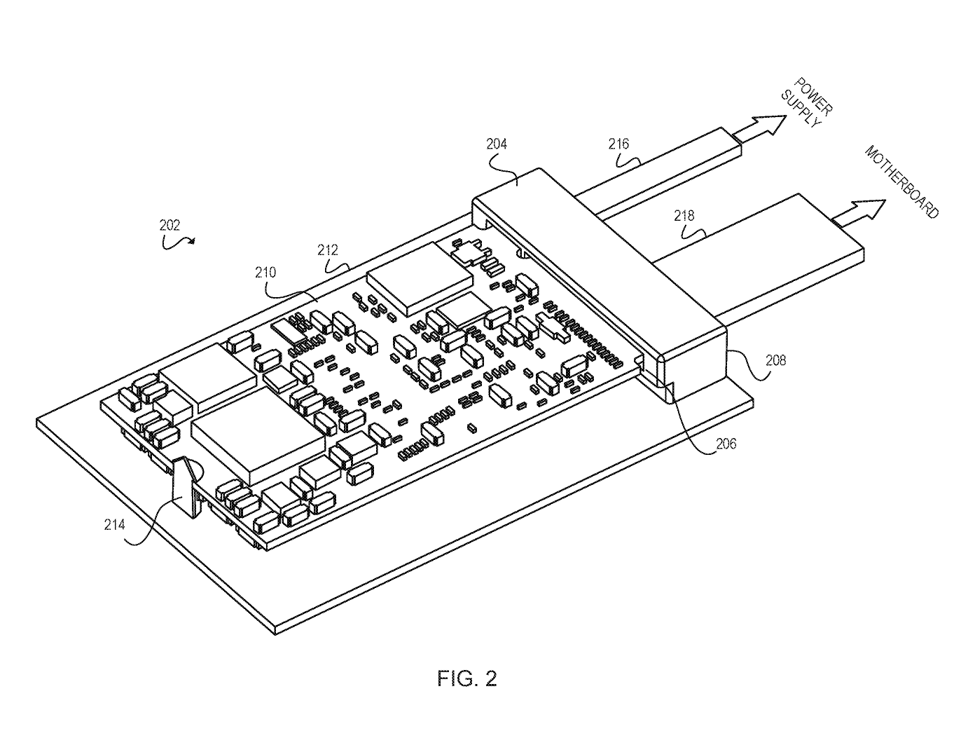

FIG. 2 is an example assembly 202 within a server. The assembly 202 includes a connector 204 with an electrical interface 206 integrated with a power cable 216 and a signal cable 218. The connector 204 further includes a mounting interface 206 in which to secure a solid state device 210. The solid state device 210 is aligned to a server chassis 212 and secured to the server chassis 212 with a mechanical fastener 214. The power cable 216 provides power through the connector 204 to the solid state device 210. In this implementation, the power cable 216 is connected to a power supply to provide power to the solid state device 210. The signal cable 218 provides signals between the solid state device 210 and a motherboard. Providing signals between the solid state device 210 and the motherboard enables the solid state device 210 to provide functionality to the motherboard while being located off the motherboard. For example, the signal cable 218 may provide communications back and forth between the solid state device 210 and the motherboard even though the solid state device 210 and the motherboard are in different physical locations within a computing system. Additionally, FIG, 2 may include other components not illustrated. For example, FIG. 2 may include the power supply and/or the motherboard connected to the power cable 216 and the signal cable 218. The connector 204, the electrical interface 208, the power cable 216, the signal cable 218, the mounting interface 206, and the solid state device 210 are similar in structure and functionality to the connector 104, the electrical interface 108, the power cable 116, the signal cable 118, the mounting interface 106, and the solid state device 110 as in FIG. 1.

The mechanical fastener 214 is a mechanical component that secures the solid state device 210 to prevent movement of the solid state device 210. Preventing movement of the solid state device 210 protects the solid state device 210 from suffering damage. In one implementation, the mechanical fastener 214 includes a holder in which the solid state device 210 slides into. In this implementation, a tolerance of physical space is between the underside of the solid state device 210 and the server chassis 212. This implementation is described in detail in the next figure.

The server chassis 212 is a frame for the server which receives the connector 204. The server chassis 212 aligns the solid state device 210 in the off motherboard location. In one implementation, the server chassis 212 may include a structure framework, mechanical guide, or other type of indicator in which to align the solid state device 210 to the server chassis 212. For example, in one implementation, the server chassis 212 may include a hole in which to guide the solid state device 210 to the accurate off motherboard location.

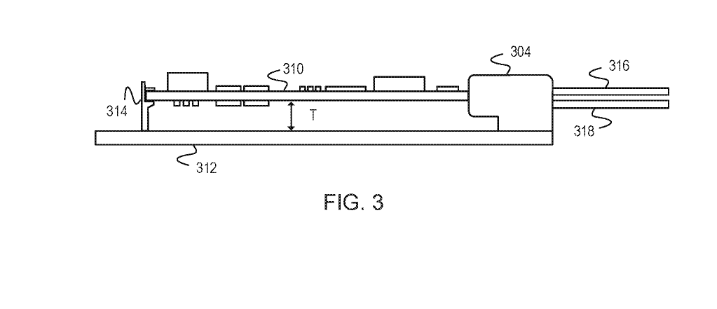

FIG. 3 is side perspective view of the example assembly as in FIG. 2. The example assembly includes a connector 304, cables 316 and 318, solid state device 310, and mechanical fastener 314 to secure the solid state device 310 to a server chassis 312. Further, FIG, 3 illustrates a tolerance (T) of space between the solid state device 310 and the server chassis 312. The solid state device 310 is located in an off motherboard location with the tolerance (T) between the solid state device 310 and the server chassis 312. The tolerance (T) is a physical dimension of space between an underside of the solid state device 310 and the server chassis 312. In this implementation, the server chassis 312 may consist of an electrical conduction material, thus the tolerance (T) may prevent the solid state device 310 from grounding to the server chassis 312.

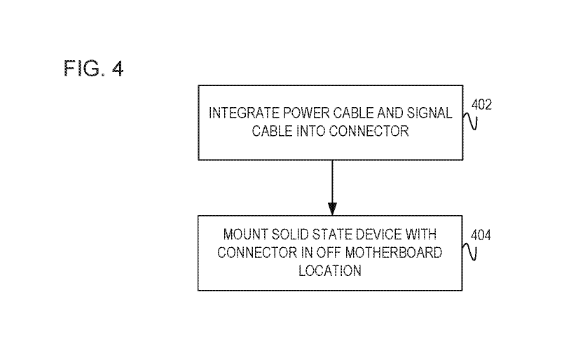

FIG. 4 is a flowchart of an example method to produce a solid state device secured by a connector in an off motherboard location. The example method secures the solid state device in the off motherboard location by integrating a power cable and a signal cable into a connector and mounting the solid state device in the connector in the off motherboard location. The off motherboard location is an area within a computing device that includes the solid state device of which is not on the motherboard. In this sense, the solid state device is attached in the location off motherboard, which may include, but should not be limited to not attaching the solid state device above, below, adjacent, or other type of direct attachment of the solid state device to the motherboard. Securing the solid state device in the off motherboard location provides flexibility as the solid state device may be located in an area where space may allow. Further, the solid state device may provide additional storage space that may be restricted on the motherboard. In one implementation, the solid state device provides storage within a server. In this implementation, the solid state device includes an M.2 drive which provides a more flexible physical specification, thus reducing an overall real estate within a computing system. The method described in FIG. 4 may include a manufacture and production of securing the solid state device in the off motherboard location. In discussing FIG. 4, references may be made to the components in FIGS. 1-3 to provide contextual examples. Further, although FIG. 4 is described as implemented by the components illustrated in FIGS. 1-3, it may be executed on other suitable components. For example, FIG. 4 may be implemented by a controller and/or processor to secure the solid state device in the off motherboard location.

At operation 402, the power cable and the signal cable are integrated into the connector. The connector is an electrical component which provides electrical connections between components. Integrating the power cable and the signal cable into the connector provides electrical connections between the solid state device and the cables. Providing the electrical connections enables the solid state device to receive power and transmit and receive communications to and from other computing systems. The power cable is an assembly of at least one electrical conductor used for a transmission of the electrical power from a power supply to the solid state device. The signal cable is an assembly of at least one signal carrier used to transmit signals between the solid state device and another computing device. In one implementation, the signal cable carries signals between the solid state device and the motherboard. The connector is located in the off motherboard location which may include soldering and/or connecting the connector in the off motherboard location to support the connector with the integrated cables and the solid state device as at operation 404.

At operation 404, the solid state device is mounted with the connector in the off motherboard location. Mounting the solid state device with the connector enables the solid state device to connect with the connector and thus aligning the electrical contacts between the power cable, signal cable, and the solid state device in this manner, the connector brings together the solid state device and the cables. This enables the solid state device to transmit and receive power and other signals. Mounting the solid state device with the connector may include but should not be limited to placing, attaching, connecting, securing, coupling, combining, associating, linking, and/or joining. In one implementation, operation 404 may include securing the solid state device with a mechanical fastener. In another implementation, operation 404 may include aligning the solid state device with a server chassis.

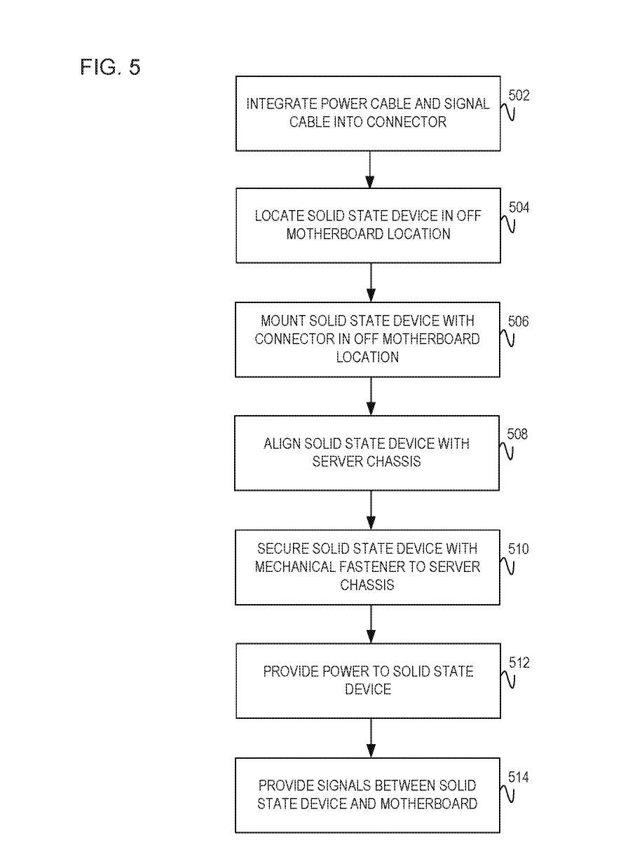

FIG. 5 is a flowchart of an example method to secure a solid state device in an off motherboard location by mounting the solid state device with a connector in the off motherboard location. The example method further includes aligning the solid state device with a server chassis, and securing the solid state device with a mechanical fastener to the server chassis. The solid state device provides additional storage within the server when a motherboard may be limited in space. Placing the solid state device in the off motherboard location provides a flexible design to enable a real estate reduction of a server. The method described in FIG. 5 may include a manufacture and production of securing the solid state device in the off motherboard location. In discussing FIG. 5, references may be made to the components in FIGS. 1-3 to provide contextual examples. Further, although FIG. 5 is described as implemented by the components illustrated in FIGS. 1-3, it may be executed on other suitable components. For example, FIG. 5 may be implemented by a controller and/or processor to secure the solid state device in the off motherboard location.

At operation 502, the power cable and the signal cable are integrated into the connector. In operation 502, the connector is located in the off motherboard location. Placing the connector in the off motherboard location enables the off motherboard location for the cables and the solid state device. Operation 502 may be similar in functionality to operation 402 as in FIG. 4.

At operation 504, the solid state device is located in the off motherboard location. In one implementation of operation 504, locating the solid state device in the off motherboard location includes providing a tolerance of space between the solid state device and the server chassis. In another implementation of operation 504 may include performing operation 510 to secure the solid state device with the mechanical fastener.

At operation 506, the solid state device is mounted in the connector in the off motherboard location. Operation 506 may be similar in functionality to operation 404 as in FIG. 4.

At operation 508, the solid is aligned with the server chassis. In one implementation, the server chassis may include a structure framework, mechanical guide, or other type of indicator in which to align the solid state device to the server chassis. For example, the server chassis may include at least one hole in which to align to the solid state device. Aligning the solid state device to the server chassis, the method may proceed to operation 510 to secure the solid state device with a mechanical fastener to the server chassis.

At operation 510, the solid state device is further secured with the mechanical fastener to the server chassis. Securing the solid state device with the mechanical fastener prevents movement of the solid state device. In another implementation of operation 510, the server chassis receives the connector in which to align the solid state device in the off motherboard location.

At operation 512, the power cable provides power to the solid state device. In one implementation, the power cable may be connected to a power supply in which to provide an electrical charge to the solid state device. The solid state device may serve as a storage device for the server, thus applying an electrical charge to the solid state device may enable operations, such as read and/or write.

At operation 514, the signal cable integrated into the connector provides signals between the solid state device and the motherboard. Providing signals between the solid state device and the motherboard, enables communications between these devices so the motherboard may access storage within the solid state device.

In summary, examples disclosed herein a flexible design through securing a solid state device in an off motherboard location. Securing the solid state device in the off motherboard location, saves space and volume on a motherboard which may provide overall better space utilization.

1. An assembly comprising:
a connector comprising:
an electrical interface integrated with a power cable and a signal cable, the power cable to provide power to a solid state device and the signal cable to provide signals between the solid state device and a computing system; and
a mounting interface to secure the solid state device with the connector in an off motherboard location; and
a mechanical fastener to secure the solid state device in the off mother board location, the mechanical fastener prevents movement of the solid state device.

2. The assembly of claim 1 wherein the computing system includes a motherboard and the assembly is further comprising:
the power cable to provide the power to the solid state device from a power supply; and
the signal cable to provide signals between the solid state device and the motherboard.

3. (canceled)

4. The assembly of claim 1 wherein the solid state device includes an M.2 solid state drive.

5. The assembly of claim 1 further comprising:
the solid state device to provide storage within a server.

6. The assembly of claim 1 further comprising:
a server chassis to receive the connector to align the solid state device in the off motherboard location.

7. The assembly of claim 1 wherein the solid state device is located in the off motherboard location with a tolerance between the solid state device and a server chassis.

8. A method comprising:
integrating a power cable and a signal cable into a connector; and
mounting a solid state device with the connector to secure the solid state device in an off motherboard location; and
securing the solid state device with a mechanical fastener to a server chassis, the mechanical fastener preventing movement of the solid state device.

9. (canceled)

10. The method of claim 8 wherein the solid state device includes an M.2 solid state drive to provide storage to a server.

11. The method of claim 8 further comprising:
locating the solid state device in the off motherboard location.

12. The method of claim 8 further comprising:
providing power to the solid state device through the power cable; and
providing signals between the solid state device and a motherboard through the signal cable.

13. The method of claim 8 further comprising:
aligning the solid state device with a server chassis.

14. A connector comprising:
an electrical interface to provide power and signals between a solid state device and a computing system; and
a mounting interface to align the solid state device with the connector, the mounting interface secures the solid state device in an off motherboard location;
a server chassis to receive the electrical interface and the mounting interface; and
a mechanical fastener to align the solid state device to the server chassis, the mechanical fastener prevents movement of the solid state device and provides a space tolerance between the solid state device and the server chassis.

15. (canceled)
